(19) United States
(12) Patent Application Publication
(10) Pub. No.: US 2025/0261298 A1
(43) Pub. Date: Aug. 14, 2025

(54) ELECTRONIC DEVICE

(71) Applicant: DENSO CORPORATION, Kariya-city (JP)

(72) Inventor: Fumikazu NIHEI, Kariya-city (JP)

(21) Appl. No.: 19/013,216

(22) Filed: Jan. 8, 2025

(30) Foreign Application Priority Data
Feb. 9, 2024 (JP) 2024-018753

(51) Int. Cl. H05K 1/02

(52) U.S. Cl. CPC H05K 1/0203; H05K 2201/09381; H05K 2201/09418; H05K 2201/2081

(57) ABSTRACT

An electronic device includes an electronic component and a circuit board. The electronic component has a heat dissipation pad. The circuit board has a heat dissipation land and an over resist. The heat dissipation land is formed to protrude from a surface of the circuit board and receives heat from the heat dissipation pad. The over resist is a solder resist arranged on a surface of the heat dissipation land, so as to cover at least a part of an outer periphery of the heat dissipation land, and a resist opening is formed on the surface of the heat dissipation land.

### CROSS REFERENCE TO RELATED APPLICATION

This application is based on Japanese Patent Application No. 2024-018753 filed on Feb. 9, 2024, the disclosure of which is incorporated herein by reference.

### TECHNICAL FIELD

The present disclosure relates to an electronic device.

### BACKGROUND

A circuit board has a connection terminal formed on the surface of the circuit board. An electronic component has a connection terminal formed on the surface of the electronic component. The circuit board and the electronic component are soldered together in a state where the connection terminal of the circuit board faces the connection terminal of the electronic component.

### SUMMARY

According to an aspect of the present disclosure, an electronic device includes an electronic component and a circuit board. The electronic component has a heat dissipation pad on a surface that faces the circuit board, when the electronic component is mounted on the circuit board, to emit heat generated in the electronic component.

The circuit board has a heat dissipation land and an over resist. The heat dissipation land is formed to protrude from a surface of the circuit board that faces the electronic component, when the electronic component is mounted on the circuit board, and receive heat from the heat dissipation pad.

The over resist is a solder resist arranged on a surface of the heat dissipation land to cover at least a periphery of the heat dissipation land and to form a resist opening on the surface of the heat dissipation land.

### BRIEF DESCRIPTION OF DRAWINGS

FIG. 1 is a cross-sectional view showing an electronic device according to a first embodiment.

FIG. 2 is a bottom view illustrating an electronic component of the electronic device.

FIG. 3 is a plan view illustrating a circuit board of the electronic device in the first embodiment.

FIG. 4 is a cross-sectional view of an electronic device in which a solder fillet has a bulging shape.

FIG. 5 is a plan view of a circuit board according to a second embodiment.

FIG. 6 is a cross-sectional view showing an electronic device of the second embodiment.

FIG. 7 is a plan view of a circuit board according to a third embodiment.

FIG. 8 is a plan view of a circuit board according to a fourth embodiment.

FIG. 9 is a plan view of a circuit board according to a fifth embodiment.

FIG. 10 is a cross-sectional view of an electronic device of the fifth embodiment.

### DETAILED DESCRIPTION

A circuit board has connection terminals formed on the front surface of the circuit board. An electronic component has connection terminals formed on the back surface of the electronic component. The circuit board and the electronic component are soldered together in a state where the connection terminals of the circuit board face the connection terminals of the electronic component.

As a result of detailed study by the inventor, the reliability of connection is lowered in the electronic device, if the electronic component is tilted relative to the circuit board when mounting the electronic component on the circuit board. This is because the solder applied to the connection point for mounting the electronic component on the circuit board (i.e., solder fillet) will bulge, causing a poor connection.

The present disclosure aims to provide an electronic device in which a connection failure is reduced.

According to an aspect of the present disclosure, an electronic device includes an electronic component and a circuit board. The electronic component has a heat dissipation pad on a surface that faces the circuit board, when the electronic component is mounted on the circuit board, to emit heat generated in the electronic component.

The circuit board includes a heat dissipation land and an over resist. The heat dissipation land is formed to protrude from a surface of the circuit board that faces the electronic component, when the electronic component is mounted on the circuit board, and receive heat from the heat dissipation pad.

The over resist is a solder resist arranged on a surface of the heat dissipation lands to cover at least a part of a periphery of the heat dissipation land and to form a resist opening on the surface of the heat dissipation land.

In the electronic device configured as above, the over resist is disposed so as to protrude from the surface of the heat dissipation land. Therefore, in the electronic device of the present disclosure, the over resist can regulate the arrangement of electronic component so that the surface of the circuit board and the surface of the electronic component do not come close to each other when the electronic component is mounted on the circuit board. As a result, in the electronic device of the present disclosure, the electronic component is restricted from tilting relative to the circuit board when mounting the electronic component on the circuit board. Thus, the solder fillet is restricted from bulging, to reduce connection failures in the electronic device.

### First Embodiment

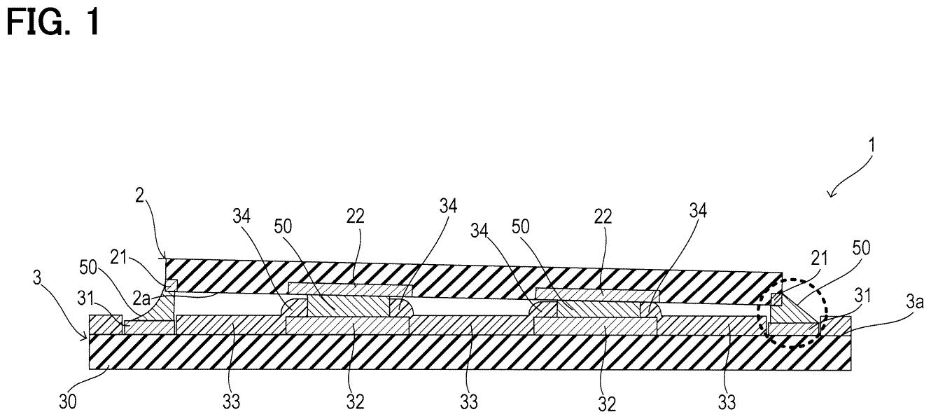

A first embodiment of the present disclosure will be described with reference to the drawings. As shown in FIG. 1, an electronic device 1 includes an electronic component 2 and a circuit board 3. The electronic device 1 is configured by housing the electronic component 2 and the circuit board 3 in a housing (not shown).

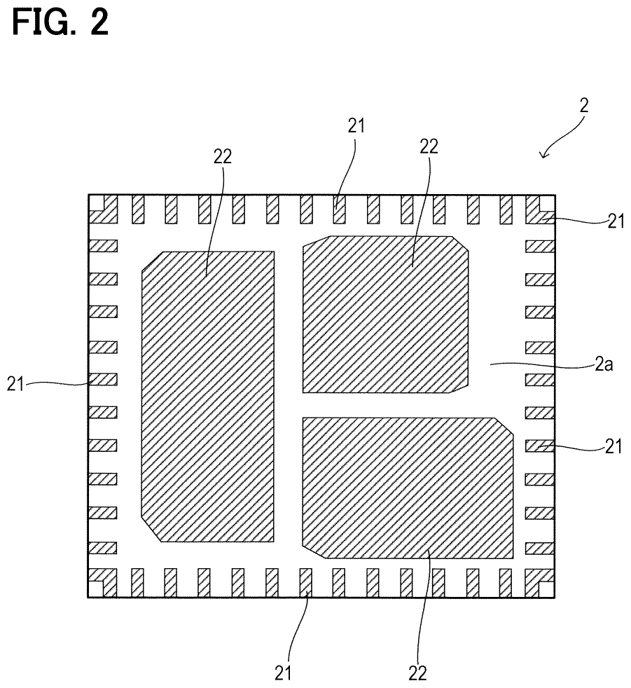

The electronic component 2 is, for example, a power module IC, and has a first surface 2a mounted on the circuit board 3. As shown in FIG. 2, the power module IC has a quad flat non-leaded package (QFN) structure, in which plural electrode pads 21 are provided along the outer periphery of the first surface 2a.

Heat dissipation pads 22 are formed on the first surface 2a, to dissipate heat generated inside the electronic component 2, and located inside the electrode pads 21 arranged along the outer periphery of the first surface 2a.

As shown in FIG. 1, the circuit board 3 is a wiring board (for example, a printed circuit board) in which various wiring patterns are formed on an insulating base material 30. The circuit board 3 has a mounting surface 3a on which the electronic component 2 is mounted. The mounting surface 3a is provided with plural lands 31 that form a part of the wiring, and heat dissipation lands 32 that receive heat from the heat dissipation pad 22 of the electronic component 2. The lands 31 and the heat dissipation lands 32 are formed to protrude from the mounting surface 3a.

The lands 31 are disposed to face the electrode pads 21 of the electronic component 2, respectively. The heat dissipation lands 32 are disposed to oppose the heat dissipation pads 22 of the electronic component 2, respectively.

The solder resist 33 is disposed on the mounting surface 3a of the circuit board 3 to cover at least the area where the lands 31 and the heat dissipation lands 32 are not formed. However, the solder resist 33 is disposed to cover a part of the surface of the heat dissipation land 32. Hereinafter, a part of the solder resist 33 that covers the surface of the heat dissipation land 32 will be referred to as an over resist 34.

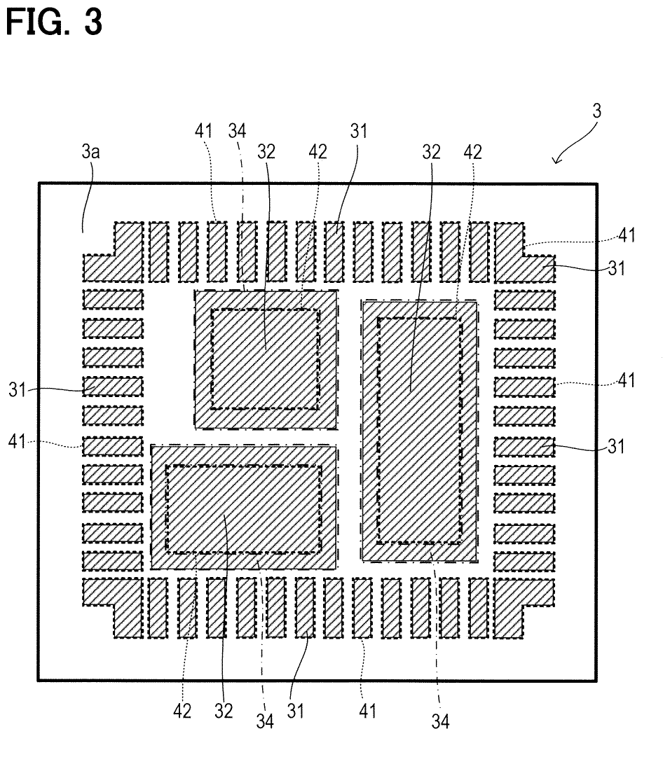

As shown in FIG. 3, the resist opening 41 is formed for all of the lands 31 so that the entire surface of the lands 31 is exposed. Further, for all of the heat dissipation lands 32, the resist opening 42 is formed adjacent to the outer periphery of the heat dissipation lands 32 so that the solder resist 33 covers the heat dissipation lands 32. In FIG. 3, a region surrounded by a single chain line corresponds to the over resist 34.

As shown in FIG. 1, the electronic component 2 is arranged on the circuit board 3 such that the lands 31 face the electrode pads 21 respectively and that the heat dissipation lands 32 oppose the heat dissipation pads 22, respectively. The lands 31 and the electrode pads 21 are respectively joined with each other by the solder 50. Furthermore, the heat dissipation lands 32 and the heat dissipation pads 22 are respectively joined with each other by the solder 50.

The electronic device 1 configured in this manner includes the electronic component 2 and the circuit board 3. The electronic component 2 has the heat dissipation pads 22 on the surface 2a that opposes the circuit board 3, when the electronic component 2 is mounted on the circuit board 3, to emit heat generated in the electronic component 2.

The circuit board 3 includes the heat dissipation land 32 and the over resist 34. The heat dissipation land 32 is formed to protrude from the surface 3a that faces the electronic component 2, when the electronic component 2 is mounted on the circuit board 3, to receive heat from the heat dissipation pad 22.

The over resist 34 is the solder resist 33 arranged on the surface of the heat dissipation land 32 to cover the surface of the heat dissipation land 32 around at least a part of the outer periphery of the heat dissipation land 32 and to form the resist opening 42 on the surface of the heat dissipation land 32.

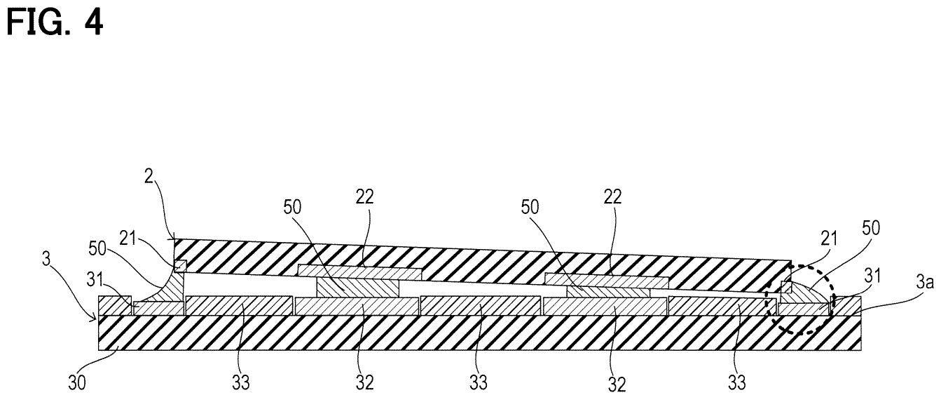

In the electronic device 1, the over resist 34 is disposed to protrude from the surface of the heat dissipation land 32. Therefore, in the electronic device 1, the over resist 34 can regulate the positioning of the electronic component 2 so that the surface 3a of the circuit board 3 and the surface 2a of the electronic component 2 facing each other do not come close to each other when the electronic component 2 is mounted on the circuit board 3. This makes it possible for the electronic device 1 to restrict the electronic component 2 from tilting with respect to the circuit board 3 when the electronic component 2 is mounted on the circuit board 3. Therefore, in the electronic device 1, it is possible to suppress the occurrence of a situation in which the solder fillet has a bulging shape, as shown by the solder 50 within a dashed circle in FIG. 1, so as to reduce connection defects in the electronic device 1. If the over resist 34 is not present, when the electronic component 2 is mounted on the circuit board 3, the inclination of the electronic component 2 with respect to the circuit board 3 becomes large. In this case, for example, as shown by the solder 50 within a dashed circle in FIG. 4, the solder fillet has a bulging shape.

### Second Embodiment

A second embodiment will be described with reference to the drawings. In the second embodiment, portions different from the first embodiment will be described. Common configurations are denoted by the same reference numerals.

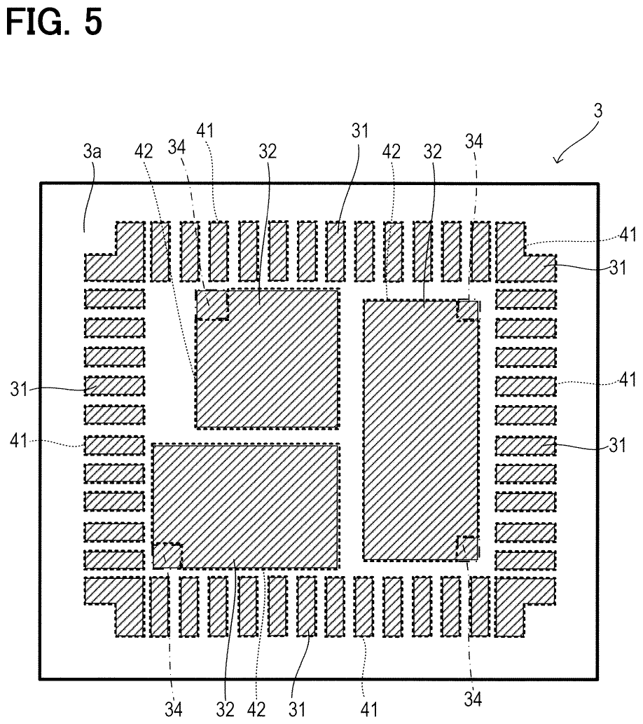

The electronic device 1 of the second embodiment differs from the first embodiment in that the arrangement of the over resist 34 is changed. As shown in FIG. 5, the circuit board 3 of the second embodiment has the four corners (hereinafter referred to as the array corners) of a rectangle formed by arranging the lands 31. Further, the three heat dissipation lands 32 formed in a rectangular shape in a planar view has plural corners (hereinafter referred to as the heat dissipation land corners). The resist opening 42 is formed so that the solder resist 33 covers the corner of the heat dissipation land 32 located the closest to the array corner. In FIG. 5, the area surrounded by the dashed line on the surface of the corner of the heat dissipation land corresponds to the over resist 34.

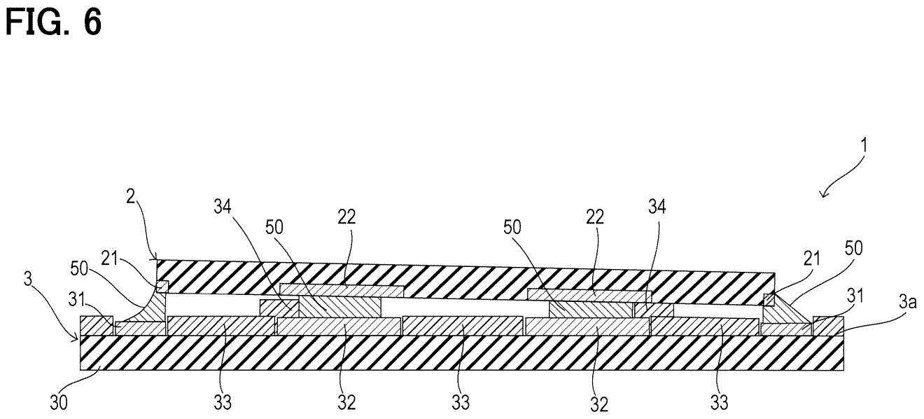

As shown in FIG. 6, the solder resist 33 is applied so that the entire surface of the heat dissipation land 32 is exposed. Then, the solder resist 33 is further applied so as to cover the corner of the heat dissipation land 32, thereby providing the over resist 34 at the corner of the heat dissipation land 32.

In the electronic device 1 configured in this manner, the over resist 34 is provided so as to cover only the corner of the heat dissipation land 32, of the outer periphery of the heat dissipation lands 32 formed in a rectangular shape.

In the electronic device 1, the over resist 34 is disposed to protrude from the surface of the heat dissipation land 32. As a result, it is possible to restrict the electronic component 2 from tilting relative to the circuit board 3 when mounting the electronic component 2 on the circuit board 3. Thus, it is possible to restrict the solder fillet from bulging, to reduce connection failures in the electronic device 1.

### Third Embodiment

A third embodiment will be described with reference to the drawings. In the third embodiment, portions different from those of the first embodiment will be described. Common configurations are denoted by the same reference numerals.

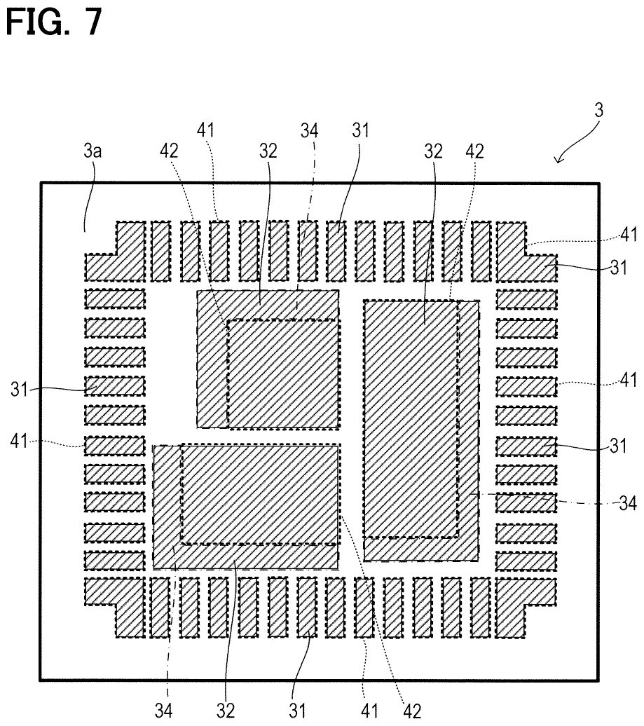

The electronic device 1 of the third embodiment is different from the first embodiment in that the arrangement of the over resist 34 is changed. As shown in FIG. 7, in the circuit board 3 of the third embodiment, the resist opening 42 is formed so that the solder resist 33 covers the heat dissipation land 32 near the outer periphery facing the lands 31, of the heat dissipation lands 32 arranged on the inner side of the lands 31. In FIG. 7, the region surrounded by the dashed line corresponds to the over resist 34.

In the electronic device 1 configured in this manner, the over resist 34 is arranged to cover only the outer periphery of the heat dissipation lands 32 that oppose the lands 31. The heat dissipation lands 32 are arranged inside the lands 31 arranged to surround the heat dissipation lands 32 on the surface 3a.

In the electronic device 1, the over resist 34 is disposed to protrude from the surface of the heat dissipation land 32. As a result, it is possible to restrict the electronic component 2 from tilting relative to the circuit board 3 when mounting the electronic component 2 on the circuit board 3. Thus, it is possible to restrict the solder fillet from bulging, to reduce connection failures in the electronic device 1.

### Fourth Embodiment

A fourth embodiment will be described with reference to the drawings. In the fourth embodiment, portions different from those of the first embodiment will be described. Common configurations are denoted by the same reference numerals.

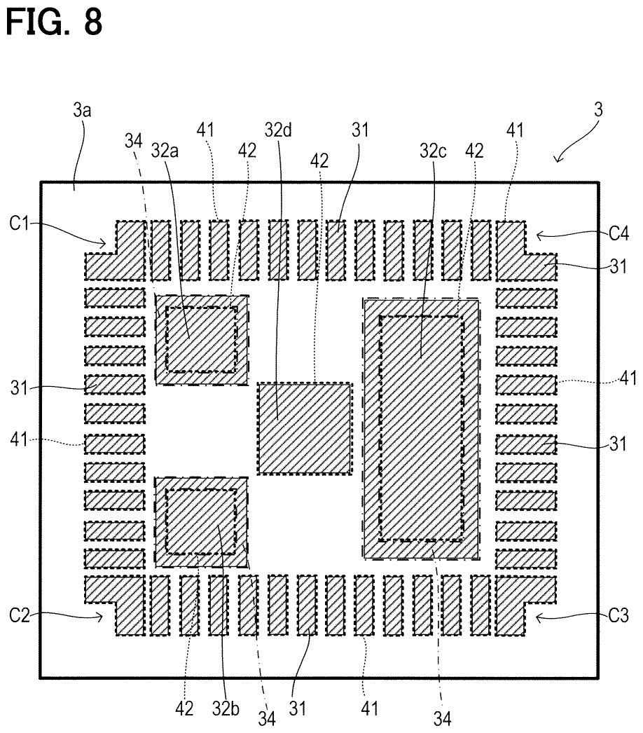

The electronic device 1 of the fourth embodiment differs from the first embodiment in that the arrangement of the heat dissipation lands 32 and the arrangement of the over resists 34 are changed. As shown in FIG. 8, in the circuit board 3 of the fourth embodiment, four heat dissipation lands 32 are arranged on the surface 3a. The lands 31 are arranged in a rectangular shape so as to surround the four heat dissipation lands 32.

The first heat dissipation land 32a of the four heat dissipation lands 32 is positioned near the first corner C1 of the four corners of the rectangle formed by the arrangement of the lands 31.

The second heat dissipation land 32b of the four heat dissipation lands 32 is positioned near the second corner C2 of the four corners of the rectangle formed by the arrangement of the lands 31. The second corner C2 is opposite to the first corner C1 along one side of the rectangle formed by arranging the lands 31.

The third heat dissipation land 32c of the four heat dissipation lands 32 is positioned near two corners, specifically the third corner C3 and the fourth corner C4 of the four corners of the rectangle formed by arranging the lands 31. The third corner C3 is opposite to the first corner C1 along a diagonal line of the rectangle formed by arranging the lands 31. The fourth corner C4 is opposite to the second corner C2 along a diagonal line of the rectangle formed by arranging the lands 31. That is, the third heat dissipation land 32c is formed to extend from the vicinity of the third corner C3 to the vicinity of the fourth corner C4.

The fourth heat dissipation land 32d of the four heat dissipation lands 32 is disposed between the heat dissipation land 32a, 32b and the third heat dissipation land 32c.

In the circuit board 3 of the fourth embodiment, the resist opening 42 is formed, such that the solder resist 33 covers the heat dissipation land 32, at the vicinity of the outer periphery of the heat dissipation land 32 constructed by the first, second, and third heat dissipation lands 32a, 32b, and 32c. For the fourth heat dissipation land 32d, the resist opening 42 is formed so that the entire surface of the heat dissipation land 32 is exposed. In FIG. 8, the region surrounded by the dashed line corresponds to the over resist 34.

In the electronic device 1 configured in this manner, the over resist 34 is provided to cover the surface of the heat dissipation land 32 at least in a part of the periphery of the heat dissipation lands 32.

In the electronic device 1, the over resist 34 is disposed to protrude from the surface of the heat dissipation land 32. As a result, it is possible to restrict the electronic component 2 from tilting relative to the circuit board 3 when mounting the electronic component 2 on the circuit board 3. Thus, it is possible to restrict the solder fillet from bulging, to reduce connection failures in the electronic device 1.

### Fifth Embodiment

A fifth embodiment of the present disclosure will be described with reference to the drawings. In the fifth embodiment, portions different from those of the fourth embodiment will be described. Common configurations are denoted by the same reference numerals.

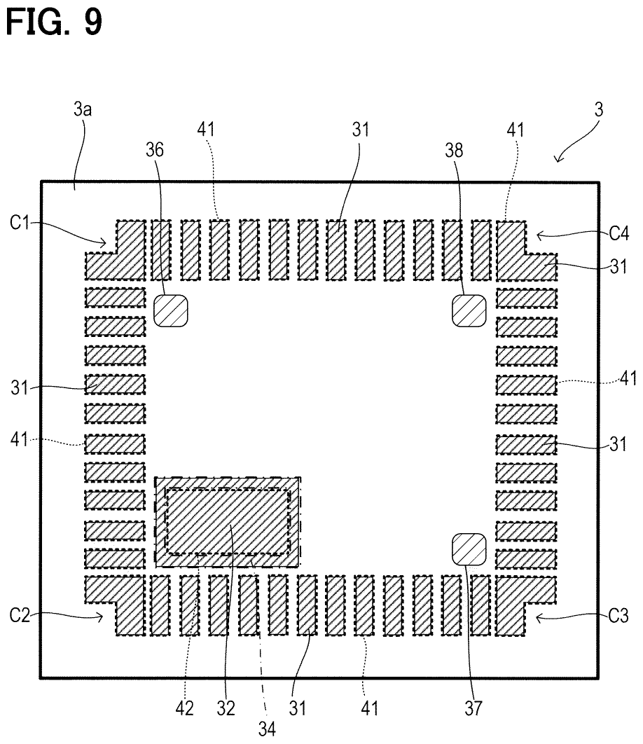

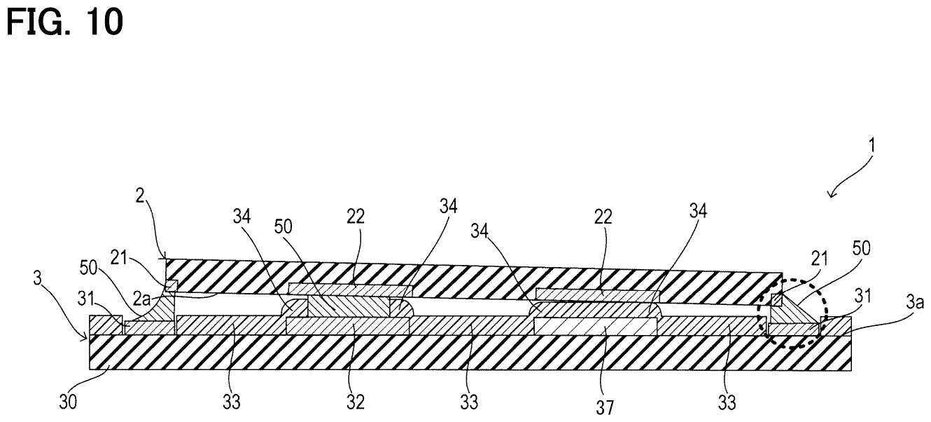

As shown in FIGS. 9 and 10, the electronic device 1 of the fifth embodiment differs from the fourth embodiment in that only one heat dissipation land 32 is provided on the circuit board 3 and three protrusions 36, 37, and 38 are provided.

In the circuit board 3 of the fifth embodiment, the lands 31 are arranged in a rectangular shape so as to surround the one heat dissipation land 32 and the three protrusions 36, 37, and 38. The one heat dissipation land 32 is disposed near the second corner C2.

The protrusions 36, 37 and 38 are disposed near the first corner C1, the second corner C2 and the fourth corner C4, respectively. The protrusions 36 to 38 are patterns formed of a metal such as copper, and are formed to be approximately the same height as the heat dissipation land 32.

In the circuit board 3 of the fifth embodiment, the resist opening 42 is formed so that the solder resist 33 covers the heat dissipation land 32 in the vicinity of the outer periphery of the heat dissipation land 32. That is, the solder resist 33 is formed so as to cover the entire surface of the protrusions 36 to 38. As a result, the solder resist 33 formed on the protrusions 36 to 38 becomes the over resist 34.

In the electronic device 1 configured in this manner, the circuit board 3 includes the plural lands 31 and the plural protrusions 36, 37, and 38. The lands 31 are arranged on the surface 3a so as to surround the one heat dissipation land 32. The protrusions 36, 37, 38 are located on the inner side of the lands 31 arranged to surround the one heat dissipation land 32, and protrude from the surface 3a within an area where the heat dissipation land 32 is not installed.

The protrusions 36, 37, 38 are provided so that a distance between the surface 3a and the surface 2a in the area where the over resist 34 is provided is the same as a distance between the surface 3a and the surface 2a in the area where the protrusions 36, 37, 38 are provided, when the electronic component 2 is mounted on the circuit board 3.

In the electronic device 1, the protrusions 36, 37, 38 can further restrict the electronic component 2 from tilting with respect to the circuit board 3 when the electronic component 2 is mounted on the circuit board 3. Therefore, it is possible to further suppress the occurrence of a situation in which the solder fillet has a bulging shape, to further reduce connection failures in the electronic device 1.

Although the embodiments of the present disclosure have been described above, the present disclosure is not limited to the embodiments and can be implemented in various modifications.

### Modification 1

In the above embodiments, the electronic component 2 has the QFN structure. Alternatively, the electronic component 2 may have a quad flat package (QFP) structure.

### Modification 2

In the fifth embodiment, the protrusions 36 to 38 are made of metal, and the solder resist 33 is formed on the protrusions 36 to 38. However, the protrusions 36 to 38 may be made of copper and the solder 50 may be applied onto the protrusions 36 to 38 so that the solder 50 on the protrusions 36 to 38 is flush with the over resist 34 on the heat dissipation land 32. Moreover, the protrusions 36 to 38 may be formed of metal so as to be at the same height as the over resist 34 on the heat dissipation land 32, and the solder resist 33 may not be formed on the protrusions 36 to 38.

What is claimed is:

1. An electronic device comprising:
a circuit board; and
an electronic component mounted on the circuit board, wherein
the electronic component has a surface opposing the circuit board,
the electronic component has at least one heat dissipation pad on the surface of the electronic component to emit heat generated in the electronic component, and
the circuit board includes:
at least one heat dissipation land protruding from a surface of the circuit board opposing the electronic component to receive heat from the at least one heat dissipation pad, respectively; and
an over resist which is a solder resist arranged on a surface of the at least one heat dissipation land to cover at least a part of an outer periphery of the at least one heat dissipation land and to form a resist opening on a surface of the at least one heat dissipation land.

2. The electronic device according to claim 1, further comprising:
a plurality of lands arranged on the surface of the circuit board to surround the at least one heat dissipation land, wherein
the over resist is arranged to cover (i) an entire periphery of the at least one heat dissipation land, (ii) only corners of the at least one heat dissipation land formed in a rectangular shape having an outer periphery, or (iii) only an outer periphery of the at least one heat dissipation land located on an inner side of the plurality of lands to face the plurality of lands.

3. The electronic device according to claim 1, further comprising:
a plurality of lands arranged on the surface of the circuit board to surround the at least one heat dissipation land; and
at least one protrusion arranged on the circuit board to protrude from the surface of the circuit board, within an area where the heat dissipation land is not provided, on an inner side of the plurality of lands, wherein
the at least one protrusion is arranged so that a distance between the surface of the circuit board and the surface of the electronic component within an area where the over resist is arranged is equal to a distance between the surface of the circuit board and the surface of the electronic component within an area where the at least one protrusion is arranged.

4. The electronic device according to claim 1, wherein the electronic component has a QFN structure or a QFP structure.
